(19) United States
(12) Patent Application Publication
(10) Pub. No.: US 2008/0135910 A1
(43) Pub. Date: Jun. 12, 2008

(54) Semiconductor device and method of fabricating the same

(75) Inventor: Kwan-young Youn, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/999,555

(22) Filed: Dec. 6, 2007

(30) Foreign Application Priority Data
Dec. 8, 2006 (KR) 10-2006-0125061

(51) Int. Cl. H01L 27/108; H01L 21/20

(52) U.S. Cl. 257/311; 438/393; 257/E27.016; 257/E21.598

(57) ABSTRACT

In a semiconductor device and a method of fabrication thereof, a semiconductor device comprises a substrate including transistors and partitioned into a memory region and a logic region. A bit line is electrically connected to at least one of the transistors in the memory region. A logic capacitor is formed on the logic region. The logic capacitor includes a logic lower metal electrode of a same layer as that of the bit line, a logic dielectric film, and a logic upper metal electrode.

### CROSS REFERENCE TO RELATED APPLICATION

This application claims priority from Korean Patent Application No. 10-2006-0125061 filed on Dec. 8, 2006 in the Korean Intellectual Property Office, the disclosure of which is incorporated herein by reference in its entirety.

### BACKGROUND OF THE INVENTION

1. Field of the Invention

Embodiments of the present invention relate to a semiconductor device and a method of fabricating the same, and more particularly, to an embedded dynamic random access memory (DRAM) device including both a logic circuit and a DRAM and a method of fabricating the same.

2. Description of the Related Art

There is an ongoing demand for ever-higher-speed operation in system-LSI circuits. In such devices, various types of systems having different features are mounted on a single, common, semiconductor substrate. For example, in some system-LSI devices, a DRAM and a logic circuit controlling the DRAM are integrated into a single chip. Such system LSI devices are referred to as an embedded DRAM, or simply eDRAM.

An eDRAM is typically composed of a memory region that forms a memory array and a logic region that forms a logic circuit to control memory operations and to perform higher-level functions and calculations.

The cell capacitor of memory devices and the logic capacitor of logic devices are different in features, performance and structure. In general, forming semiconductor devices with capacitors having different structures on a single semiconductor substrate requires separate manufacturing processes for each device. For example, a logic capacitor, such as a metal-insulator-metal (MIM) capacitor, used in the logic region, is generally formed during the metal wiring process. However, during a metal wiring process, pollution can occur by the metal used to form the MIM capacitor in the logic region. Particularly, in the metal wiring process, for example, if copper is used for the metal wiring, it can be difficult to use high-k dielectric materials as a logic dielectric film of the logic capacitor due to the risk of copper pollution. In addition, it is complicated to form a logic capacitor in the logic region, since photolithography processes need to repeated many times.

### SUMMARY OF THE INVENTION

An object of the embodiments of the present invention is to provide a semiconductor device having superior electrical characteristics.

Another object of the embodiments of the present invention is to provide the semiconductor device and a method of fabricating the semiconductor device using relatively more efficient fabrication processes.

In one aspect, a semiconductor device comprises a substrate including transistors and partitioned into a memory region and a logic region. A bit line is electrically connected to at least one of the transistors in the memory region. A logic capacitor is formed on the logic region. The logic capacitor includes a logic lower metal electrode of a same layer as that of the bit line, a logic dielectric film, and a logic upper metal electrode.

In one embodiment, the logic dielectric film is present exclusively in the logic region and is not present on the bit line of the memory region.

In another embodiment, a material of the logic lower metal electrode is the same as the bit line.

In another embodiment, the semiconductor device further comprises a hard mask layer aligned with the bit line and the logic upper metal electrode on the bit line and the logic upper metal electrode.

In another embodiment, the dielectric film is a single film or multilayered film made of oxides and nitrides of Al, Hf, Zr, La, Si, Ta, Ti, Sr, Ba, Pb, Cr, Mo, W, Y, Mn, or mixtures thereof

In another embodiment, the logic upper metal electrode is aligned with the logic dielectric film.

In another embodiment, the logic dielectric film is formed to have an area smaller than the area of the logic lower metal electrode.

In another embodiment, the semiconductor device further comprises a cell capacitor electrically connected to the transistor, wherein the cell capacitor includes a cell lower metal electrode, a cell dielectric film, and a cell upper metal electrode, and the logic dielectric film and the cell dielectric film of the cell capacitor are made of the same material.

In another embodiment, a bit line contact connecting the transistor and the bit line, the bit line, and the logic lower metal electrode are made of the same metallic material.

In another embodiment, the bit line and the logic lower metal electrode are made of W or TiN.

In another aspect, a method of fabricating a semiconductor device comprises: providing a substrate including transistors formed thereon and divided into a memory region and a logic region; and forming a bit line electrically connected to at least one of the transistors in the memory region and forming a logic capacitor on the logic region, wherein the forming of the logic capacitor includes forming a logic lower metal electrode, a logic dielectric film, and a logic upper metal electrode.

In one embodiment, the logic dielectric film is present exclusively in the logic region, and not in the memory region.

In another embodiment, forming the bit line and forming the logic lower metal electrode of the capacitor are performed at the same time so that the material of the logic lower metal electrode is the same as that of the bit line.

In another embodiment, the logic dielectric film is a single film or multilayered film made of oxides or nitrides of Al, Hf, Zr, La, Si, Ta, Ti, Sr, Ba, Pb, Cr, Mo, W, Y, or Mn, or mixtures thereof

In another embodiment, a bit line contact connecting the transistor and the bit line, the bit line, and the logic lower metal electrode are made of the same metallic material.

In another embodiment, the bit line and the logic lower metal electrode are made of W or TiN.

In another aspect, a method of fabricating a semiconductor device comprises: providing a substrate including transistors formed thereon and divided into a memory region and a logic region; forming an interlayer insulating film on the substrate; forming a metal film for a bit line and a logic lower metal electrode on the interlayer insulating film; forming an insulating film for a logic dielectric film on the metal film for the bit line and the logic lower metal electrode; forming a metal film for a logic upper metal electrode on the insulating film for a logic dielectric film; patterning the metal film for the logic upper metal electrode and the insulating film for the logic dielectric film to form the logic upper metal electrode and the logic dielectric film; and forming a bit line electrically connected to the transistor through a contact formed through the interlayer insulating film and forming a logic lower metal electrode under, the patterned logic dielectric film by patterning the metal film for the bit line and the logic lower metal electrode, so that a bit line is formed in the memory region and so that a logic capacitor is formed in the logic region.

In one embodiment the method further comprises: forming a hard mask layer on the logic upper metal electrode and the metal film for the bit line and the logic lower metal electrode after the patterning of the logic upper metal and the logic dielectric film to form the logic upper metal electrode and the logic dielectric film, wherein the patterning of the metal film for the bit line and the logic lower metal electrode after the forming of the hard mask layer includes aligning the hard mask layer with the bit line and the logic lower metal electrode or the logic upper metal electrode by patterning the hard mask layer.

In another embodiment, the logic dielectric film is a single film or multilayered film made of oxides or nitrides of Al, Hf, Zr, La, Si, Ta, Ti, Sr, Ba, Pb, Cr, Mo, W, Y, Mn, or mixtures thereof.

In another embodiment, the logic upper metal electrode and the logic dielectric film are simultaneously patterned such that the logic upper metal electrode is aligned with the logic dielectric film.

In another embodiment, the method further comprises: forming a second interlayer insulating film on the bit line and the logic capacitor after the bit line and the logic capacitor are formed; and simultaneously forming a logic upper metal electrode contact and a logic lower metal electrode contact that are electrically connected to the logic upper metal electrode and the logic lower metal electrode of the logic capacitor, respectively, in the second interlayer insulating film, wherein the forming of the logic lower metal electrode includes patterning the logic lower metal electrode in an area larger than the area of the logic dielectric film.

In another embodiment, the method further comprises forming a cell capacitor that is electrically connected to the transistor on the second interlayer insulating film, wherein the cell capacitor comprises a cell lower metal electrode, a cell dielectric film, and a cell upper metal electrode; and wherein the cell dielectric film and the logic dielectric film are made of the same material.

In another embodiment, each of the cell dielectric film and the logic dielectric film is a single film or a multilayered film made of oxides or nitrides of Al, Hf, Zr, La, Si, Ta, Ti, Sr, Ba, Pb, Cr, Mo, W, Y, Mn, or mixtures thereof

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a semiconductor device according to a first embodiment of the present invention;

FIG. 2 is a cross-sectional view of a semiconductor device according to a second embodiment of the present invention;

FIG. 3 is a cross-sectional view of a semiconductor device according to a third embodiment of the present invention;

FIG. 4 is a flow chart illustrating a method of fabricating a semiconductor device according to the second embodiment of the present invention;

FIGS. 5A to 5H are cross-sectional views sequentially illustrating a method of fabricating a semiconductor device according to the first embodiment of the present invention;

FIGS. 6A and 6B are cross-sectional views sequentially illustrating the method of fabricating a semiconductor device according to the second embodiment of the present invention; and

FIG. 7 is a cross-sectional view illustrating a method of fabricating a semiconductor according to the third embodiment of the present invention.

### DETAILED DESCRIPTION OF EMBODIMENTS

Hereinafter, aspects of the present invention will be described by explaining illustrative embodiments in accordance therewith, with reference to the attached drawings. While describing these embodiments, detailed descriptions of well-known items, functions, or configurations are typically omitted for conciseness.

It will be understood that although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

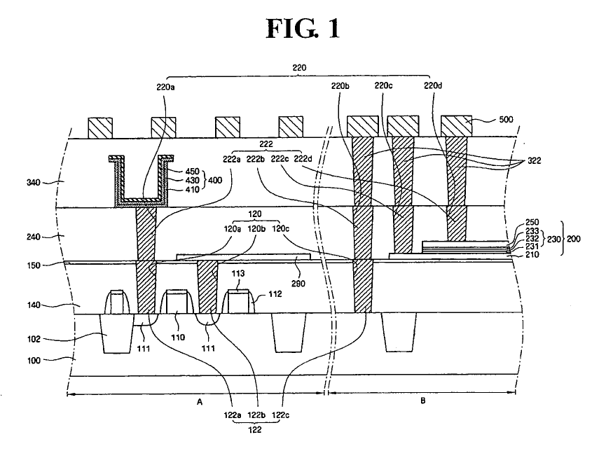

Referring to FIG. 1, an example structure of the semiconductor device according to a first embodiment of the present invention will be described as follows.

As shown in FIG. 1, a semiconductor device according to the first embodiment of the present invention may be configured to have a COB (Capacitor Over the Bit line) structure. The semiconductor device according to the first embodiment of the present invention includes a transistor, a substrate 100 that is divided into a memory region A and a logic region B, a DRAM cell including a bit line 290 that is electrically connected to one or more transistors on the memory region A and a cell capacitor 400, and a logic capacitor 200 on the logic region B.

The surface of the substrate 100 is divided into the memory region A on which a memory cell is formed, and a logic region B on which a logic circuit is formed to control the memory cell. More particularly, the semiconductor substrate 100 may be made of any of a number of suitable substrate materials, for example, Si, Ge, SiGe, GaP, GaAs, SiC, SiGeC, InAs, InP, or a mixture thereof. Moreover, the semiconductor substrate 100 may be a laminated substrate where at least two layers, including a semiconductor substance layer formed of the above-mentioned substances and an insulating layer, are layered. In one example embodiment, the semiconductor substrate 100 may be an SOI (Silicon On Insulator) substrate. An element isolation film 102 that defines an active area is formed in the semiconductor substrate 100.

First, the memory region. A is where a memory unit is positioned, and a DRAM (Dynamic Random Access Memory) cell is generally used as the memory cell of the memory unit.

The DRAM cell existing on the memory region A of the substrate 100 will be described hereafter. The DRAM cells are arranged in a matrix pattern so as to form a memory array.

The DRAM cell is designed to include a word line (not shown) that is driven by a row address, a bit line 290 that is driven by a column address, a cell transistor that is connected to the bit line 290 and the word line, and the cell capacitor 400 that is connected to the cell transistor and has data recorded therein.

Transistors including gate electrodes 110 and source/drain regions 111 are formed on the memory region A of the substrate 100. The source/drain regions 111 are formed of impurities between the gate electrodes 110 by injecting impurity ions into the semiconductor substrate 100. A gate is formed on the substrate 100 with a gate insulating film interposed therebetween, and the upper side is composed of a gate electrode 110 including a silicide film (113), a side wall spacer 112 and etc. The gate electrode 110 may be formed of, for example, a single film made of polysilicon, metal, and metal silicide or a multilayered film including the single films. The side wall spacer 112 may be a silicon nitride film.

A first interlayer insulating film 140 and an etch stop film 150 are sequentially formed on the semiconductor substrate 100 on which transistors are formed. At this time, the first interlayer insulating film 140 may be made of silicon oxide (SiO₂), such as USG (Undoped silicate Glass) and BSG (BoroSilicate Glass). Materials of the etch stop film 150 may include, for example, SiON or SiN. The etch stop film 150 is optional and can be omitted.

A first metal contact hole 120 and a first metal contact 122 are formed in the first interlayer insulating film 140 and the etch stop film 150 so as to be in contact with the source/drain regions 111 of the transistor. The first metal contacts 122 are formed as the first metal contact hole 120 is filled with conductive material; thus, devices or contact above and below the first metal contact 122 are electrically connected to each other. The conductive material filled in the first metal contact holes may include W, Ti or TiN, or a mixture thereof. The types of elements that can be electrically connected the first metal contact 122 include a contact (Buried Contact, 122a) to be connected to the cell capacitor 400, a bit line contact (Direct Contact, 122b) to be connected to the bit line 290 and a metal contact (Metal Contact, 122c) to be connected to a metal wire 500, and the like.

At this time, a barrier metal film (not shown) in the contact hole 120 improves the adhesion of the contact, and prevents impurities from diffusing at the time of depositing metallic materials. Materials of the barrier metal film may include, for example, TiN, Ti+TiN, and the like.

The bit line 290 is electrically connected to the source/drain region 111 of the transistor through the first metal contact 122b formed on the first interlayer insulating film and is driven by the column address. The bit line 290 may be made of W or TiN.

A second interlayer insulating film 240 may be formed on the bit line 290 and the first interlayer insulating film 140. Since the second interlayer insulating film 240 can be substantially identical to the first interlayer insulating film 140, description thereof will be omitted.

Second metal contacts 222 may be formed through the second interlayer insulating film 240. As shown in FIG. 1, the cell capacitor 400 may be formed on the second interlayer insulating film 240 of the memory region A. The cell capacitor 400 is formed in a cylindrical shape. The cell capacitor 400 is a MIM capacitor having a metal-dielectric film-metal structure, and includes a cell lower metal electrode 410, a cell dielectric film 430, and a cell upper metal electrode 450.

In one embodiment, the cell lower metal electrode 410 and the cell upper metal electrode 450 are metal films that can be made of W, TiN, TaN, WN, Ru, Pt, Ir, or a mixture thereof.

In various embodiments, the cell dielectric film 430 may be a single film or multilayered film made of oxides or nitrides of Al, Hf, Zr, La, Si, Ta, Ti, Sr, Ba, Pb, Cr, Mo, W, Y, Mn or mixtures thereof The cell dielectric film 430 of the cell capacitor 400 may have the same materials as those of a dielectric film 230 of the logic capacitor 200, to be described below.

If the cell dielectric film 430 is formed of, among the above-described materials, high dielectric materials (High-k), such as Al₂O₃, HfO₂, TiO₂, La₂O₃, Ta₂O₅, PrO₂, Al₂O₃, or a mixture thereof, electrostatic capacitance is likely to increase for an equal area. In other words, since a smaller area is required to gain an equal electrostatic capacitance, the semiconductor device is made to have better electrical performance and integration.

A third interlayer insulating film 340 may be formed on the cell capacitor 400, and the metal wire 500 may be formed on the third interlayer insulating film.

The logic region B includes a logic transistor (not shown) and the logic capacitor 200. The logic transistor constitutes not only a peripheral circuit which controls a DRAM but also can include various other high speed calculation functioning units. The logic capacitor 200 may include a logic lower metal electrode 210, a logic dielectric film 230, and a logic upper metal electrode 250. The logic capacitor 200 may have a planar shape.

Hereinafter, since components that coexist in the logic region B and the memory region A have already been described in the explanation of the structure on the memory region A, detailed description thereof will be omitted.

Although the logic transistor (not shown) on the logic region B may have a substantially different structure and function from that of the transistor of the memory region A, description thereof will be omitted, as those skilled in the field can fully understand related techniques that are not described.

The first interlayer insulating film 140 and the etch stop film 150 that are substantially the same as those of the memory region A may be formed on the logic transistor. The first metal contact 122c may be formed through the first interlayer insulating film 140.

The logic lower metal electrode 210 may be formed on the first interlayer insulating film 140 and the etch stop film 150. In various embodiments, the logic lower metal electrode 210 can be a metallic film made of TiN, TaN, W, WN, Ru, Pt, Ir, or a mixture thereof.

Materials of the logic lower metal electrode 210 may be equal to those of the bit line 290 of the memory region A, to be described below. The materials may be, for example, W and TiN. The logic lower metal electrode 210 and the bit line 290 of the memory region A may be formed in the first interlayer insulating film 140, and exist on the same layer.

The logic dielectric film 230 may be formed to have a smaller area than the logic lower metal electrode 210. That is, since the logic lower metal electrode 210 has a larger area than the logic dielectric film 230, although to be described below, the second metal contacts 222 that are in contact with the logic lower metal electrode 210 and the logic upper metal electrode 250, respectively, may be formed on the same layer.

The logic dielectric film 230 may be a single film or multilayered film made of oxides or nitrides of Al, Hf, Zr, La, Si, Ta, Ti, Sr, Ba, Pb, Cr, Mo, W, Y, Mn, or mixtures thereof The logic dielectric film 230 may be substantially to the same as that of the cell dielectric film 430, thus, description thereof will be omitted. However, the logic dielectric film 230 does not exist on the memory region A. More particularly, the logic dielectric film 230 does not exist on the bit line 290 of the memory region A.

In the embodiment shown, the upper metal electrode 250 of the logic capacitor 200 occupies a smaller area than the lower metal electrode 210. The upper metal electrode 250 may be formed on the dielectric film 230, and aligned with the dielectric film 230. In various embodiments, the upper metal electrode 250 may be a metallic film made of TiN, TaN, WN, Ru, Pt, Ir, or a mixture thereof.

The second interlayer insulating film 240 may be formed on the logic capacitor 200 as well as in the memory region A. The second metal contacts 222 are formed through the second interlayer insulating film 240. Contacts 222c and 222d are formed through the second interlayer insulating film 240 of the logic region B so as to be electrically connected to the logic capacitor 200 of the logic region B. More particularly, the semiconductor device includes the lower metal electrode contact 222c that is electrically connected to the lower metal electrode 210 of the logic capacitor 200 and the upper metal electrode contact 222d that is electrically connected to the upper metal electrode 250. Since the lower metal electrode 210 occupies a larger area than the upper metal electrode 250, the lower metal electrode contact 222c and the upper metal electrode contact 222d may exist on the same layer, and therefore can be simultaneously formed.

The third interlayer insulating film 340 and a third metal contact 322 penetrating the third interlayer insulating film 340 may be formed on the second interlayer insulating film 240 of the logic region B and an etch stop film (not shown). The metal wire pattern 500 is formed on the third interlayer insulating film 340 and the third metal contact 322 to complete formation of the semiconductor device.

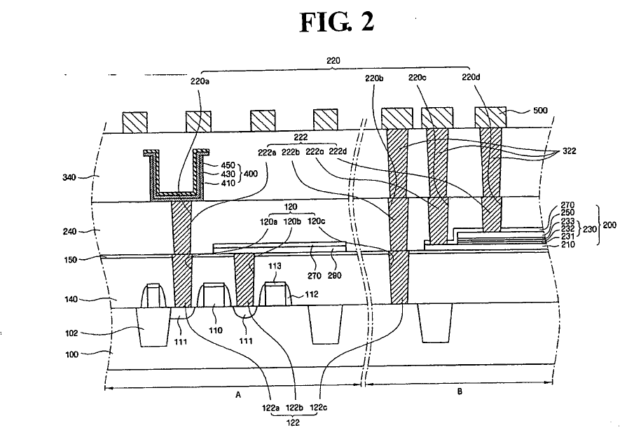

Hereinafter, a second embodiment of the present invention will be described with reference to FIG. 2. FIG. 2 is a cross-sectional view of a semiconductor device including a hard mask according to the second embodiment of the present invention. For the sake of clarity, the same components as those of the first embodiment are denoted by the same reference numerals, and the description thereof will be omitted. As shown in FIG. 2, the semiconductor device according to the second embodiment has basically the same structure as the semiconductor device according to the first embodiment, except for the following.

In the semiconductor device according to the second embodiment of the present invention, a hard mask 270 may be formed on the bit line 290 of the memory region A and the MIM capacitor 200 of the logic region B. The hard mask 270 is used in a patterning process of the bit line 290. The etching is more accurate and straightforward when using the hard mask 270 as compared to when using only photoresist to pattern, and materials of the hard mask allow fine patterns to be formed. The hard mask 270 may be, for example, a silicon oxide film, a silicon nitride film, a polysilicon film, etc, or a mixture thereof, but not limited thereto.

As shown in FIG. 2, the logic dielectric film 230 used in the logic capacitor 200 does not exist on the bit line 290 of the memory region A. Therefore, the, hard mask 270 may be formed on the upper surface of the bit line 290 of the memory region A and the upper and lateral surface of the logic upper metal electrode 250, the logic dielectric film 230 and the logic lower metal electrode 210 of the logic region B. In other words, the hard mask 270 is formed on the bit line 290 without the logic dielectric film 230 interposed therebetween.

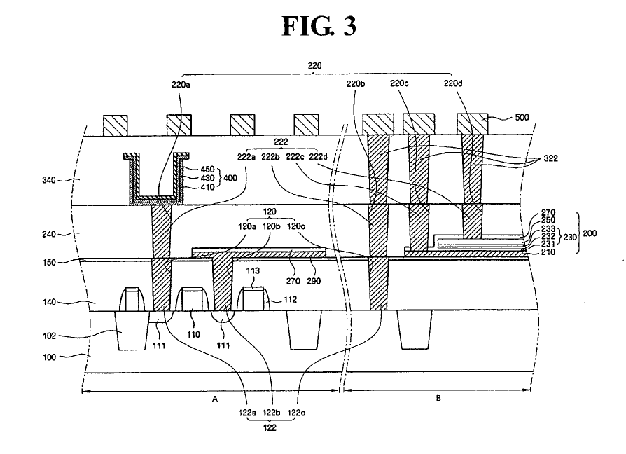

Hereinafter, a third embodiment of the present invention will be described with reference to FIG. 3. FIG. 3 is a cross-sectional view of the semiconductor device according to the third embodiment of the present invention, in which the first metal contact and the bit line are made of the same metallic material. For the sake of clarity, the same components as those of the first and second embodiments are denoted by the same reference numerals, and the description thereof will be omitted. As shown in FIG. 3, the semiconductor device according to the third embodiment has basically the same structure as the semiconductor device according to the first and second embodiments, except for the following.

In the semiconductor device according to the third embodiment of the present invention, the first metal contacts 122 and the bit line 290 of the memory region A may be made of the same materials. Therefore, the first metal contacts 122, the bit line 290 of the memory region A and the logic lower metal electrode 210 of the logic region B are made of the same material.

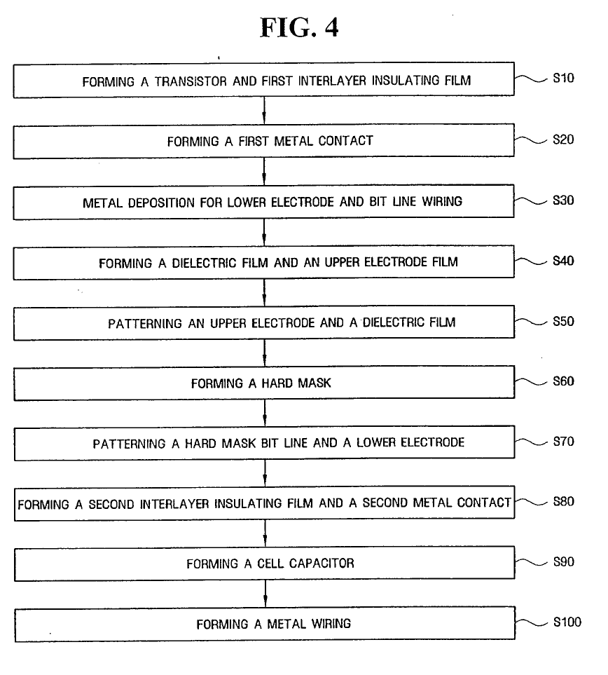

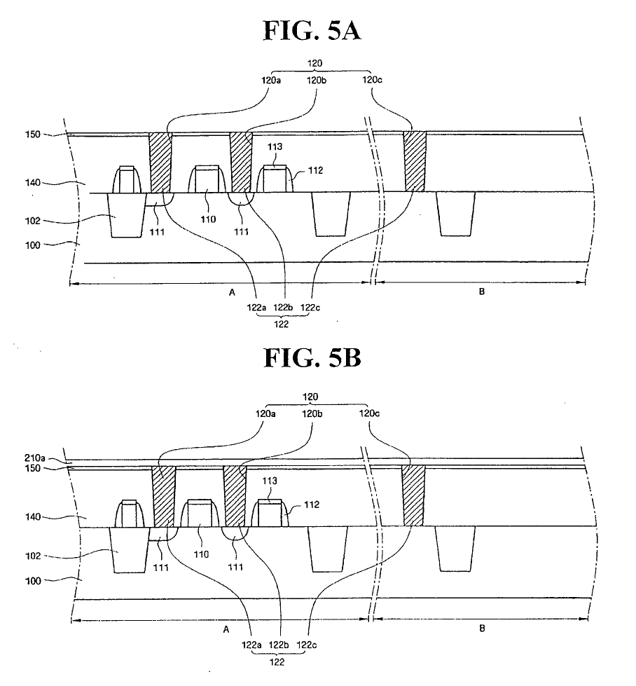

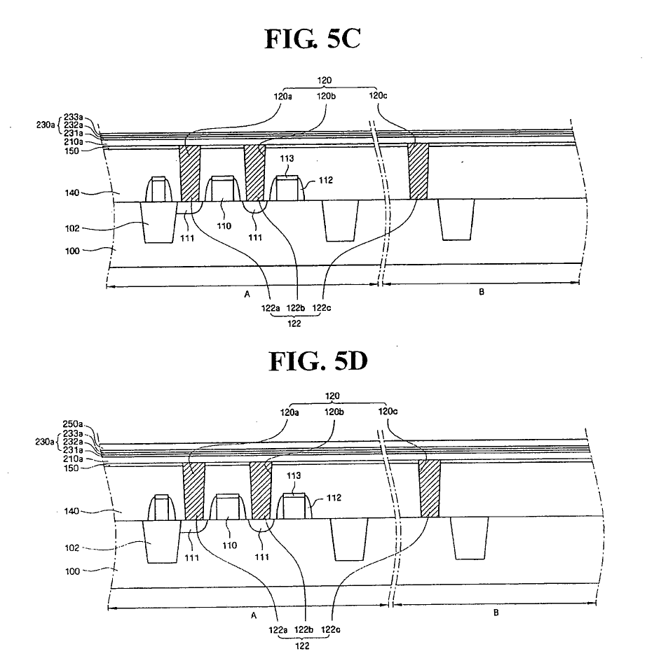

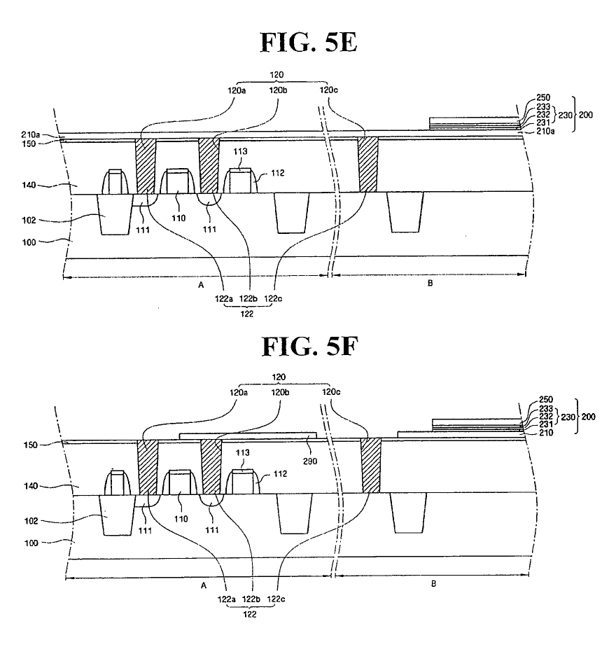

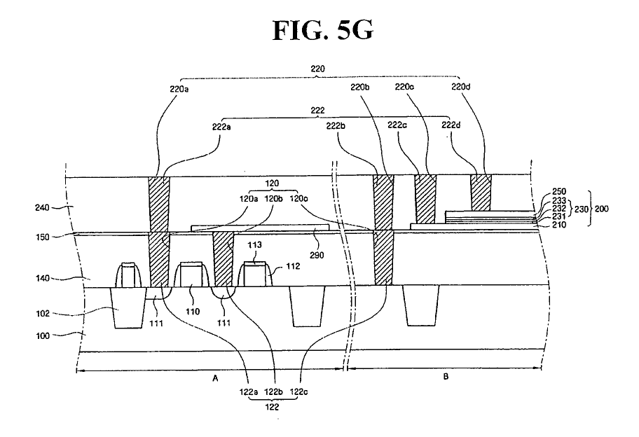

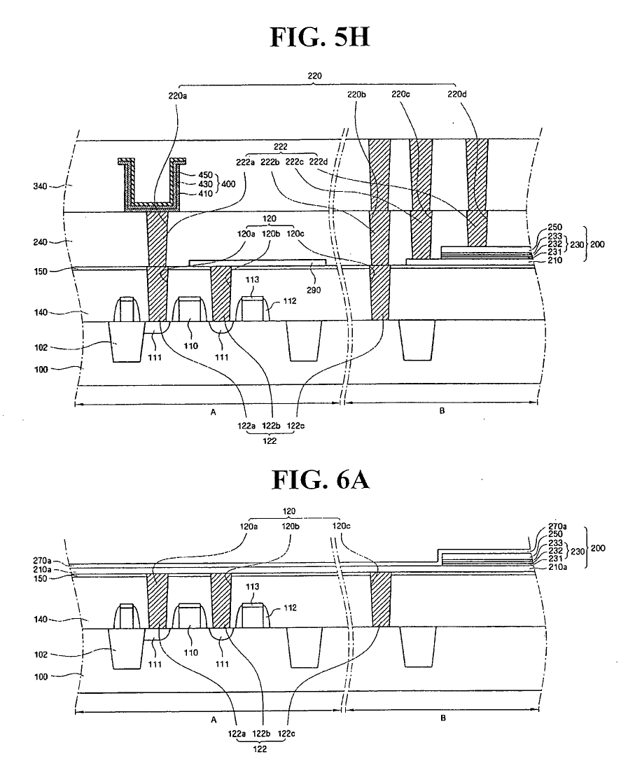

Hereinafter, a method of fabricating the semiconductor device according to the first embodiment of the present invention will be described in detail with reference to FIGS. 4 to 5H. FIG. 4 is a flow chart illustrating a method of fabricating the semiconductor device according to the second embodiment of the present invention. The method of fabricating the semiconductor device according to the second embodiment is substantially equal to the method of fabricating the semiconductor device according to the first embodiment of the present invention, except for the step of forming a hard mask (S60). In this respect, the method according to the first embodiment will be described below. FIGS. 5A to 5H are cross-sectional views illustrating the method of fabricating the semiconductor device according to the first embodiment of the present invention.

First, with reference to FIGS. 4 and 5A, a transistor is formed in the semiconductor substrate 100, and the first interlayer insulating film 140 is formed to cover the transistor (S10).

To be more specific, as shown in FIG. 3, a cell is divided into an active area and an inert area by forming the element isolation film 102 in the memory region A and the logic region B of the semiconductor substrate 100, respectively, using an element isolation process. The element isolation film 102 may be, for example, an STI (Shallow Trench Isolation).

The transistor is composed of the gate electrode 110 and the source/drain region 111. The gate electrode 110 is formed on the substrate 100 with the gate insulating film (not shown) interposed therebetween, and the upper side is composed of a gate electrode 110 including a silicide film 113, a side wall spacer 112, and the like. The side wall spacer 112 may be a silicon nitride film. The transistors may be classified into a transistor in the memory region and a logic transistor (not shown) in the logic region.

Next, the interlayer insulating film 140 and the etch stop film 150 are sequentially formed on the semiconductor substrate 100 where transistors are formed. Materials of the interlayer insulating film 140 may include silicon oxides (SiO2), such as USG (Undoped Silicate Glass) and BPSG (BoroPhospho Silicate Glass). Materials of the etch stop film 150 may include SiON or SiN. If necessary, formation of the etch stop film 150 can be omitted.

The first interlayer insulating film 140 may be formed of the material having excellent gap fill characteristics in order to fill gaps between the gate electrode 110 and the lower conductive patterns. For example, the first interlayer insulating film 140 may be O₃-TEOS, SOG, PDL (Pulsed Deposition Layer)-SiO₂, and etc.

Next, referring to FIG. 5B, the first metal contacts 122 are formed so as to be in contact with the source/drain regions 111 of the transistor (S20).

To be more specific, the first metal electrode contact 122 is formed in the interlayer insulating film 140 and the etch stop film 150 so as to be electrically connected to the source/drain region 111 of the semiconductor substrate 100.

The first metal electrode contact 122 may be formed by the following method. That is, an etch mask is formed to define an area for forming the first metal electrode contact 122. Next, as portions of the interlayer insulating film 140 and etch stop film 150 that are exposed by an etch mask are etched, formation of the first metal contact hole 120 is completed to expose the source/drain region 111.

Next, conductive materials are filled in the formed first metal electrode contact hole 120, and are subjected to a CMP (chemical mechanical polishing) or an etching-back, thereby forming the first metal contact 122. The conductive materials filled in the first metal contact 122 may include W, Ti or TiN, or a mixture thereof.

At this time, before filling the contact hole 120 with metallic materials, a barrier metal film (not shown) can be deposited. The barrier metal film is provided to enhance adhesion of the contact (glue layer), and to prevent impurities from diffusing during deposition of metallic materials. Materials of the barrier metal film may include, for example, TiN or Ti+TiN.

Next, as shown in FIG. 5B, the bit line and the lower metal electrode metal film 210a are formed (S30) of the same material.

The bit line to be used in the logic capacitor 200 and the lower metal electrode metal film 210a may be formed by methods, such as a CVD (Chemical Vapor Deposition), an LPCVD (Low Pressure Chemical Vapor Deposition), a MOCVD (Metal Organic Chemical Vapor Deposition) or an ALD (Atomic Layer Deposition), or a PVD (Physical Vapor Deposition). Since the bit line to be used in the logic capacitor 200 and the lower metal electrode metal film 210a can be formed by processes known to those skilled in the art of the present invention, detailed description of the known processes will be omitted.

The bit line and the lower metal electrode metal film 210a can, for example, be made of W, TiN, TaN, WN, Ru, Pt, Ir, etc., or a mixture thereof. Preferably, the bit line and the lower metal electrode metal film 210a may be made of W or TiN. If the bit line 290 is formed of tungsten, the thickness can be made thinner than that of a bit line made of general aluminum, which reduces coupling noise between the bit lines.

Subsequently, with reference to FIGS. 5C and 5D, an insulating film 230a for a logic dielectric film and a logic upper metal electrode film 250a are formed on the bit line and the lower metal electrode metal film 210a that are the result of FIG. 5B (S40).

The insulating film 230a for a logic dielectric film can be formed by methods, such as an ALD (Atomic Layer Deposition), a PEALD (plasma Enhanced Atomic Layer Deposition) or a CVD (chemical vapor deposition). However, since the insulating film 230a for a logic dielectric film can be formed by processes known to those skilled in the art of the present invention, detailed description of the known processes will be omitted.

The insulating film 230a for a logic dielectric film may be a single film made of oxides or nitrides of Al, Hf, Zr, La, Si, Ta, Ti, Sr, Ba, Pb, Cr, Mo, W, Y, Mn, and mixtures thereof or a multilayered film including the single films. As shown in FIGS. 1 and 5D, the dielectric film 230 may have a multilayer structure of high dielectric films (231, 232, 233 . . . ). The dielectric film 230 may be, for example, a zirconium oxide film/alumina/zirconium oxide film, or other suitable multi-layered film, but is not limited thereto.

Next, as shown in FIG. 5D, the logic upper metal electrode film 250a is formed on the result of FIG. 5C (S40).

A method of forming the upper metal electrode 250 on the dielectric film 230 may be substantially equal to a method of forming the bit line and the lower metal electrode metal film 210a on the semiconductor substrate. For example, like the bit line and the lower metal electrode metal film 210a, the upper metal electrode 250 can also be formed of TiN, TaN, WN, Ru, Pt, Ir, or a mixture thereof.

Next, as shown in FIG. 5E, the logic upper electrode film 250a and the logic dielectric film 230a are patterned, and, as such, formation of the logic upper electrode 250 and the logic dielectric film 230 is completed (S50).

In various embodiments, the logic upper electrode film 250a and the insulating film 230a for a logic dielectric film can be sequentially patterned, or, optionally, simultaneously patterned. If the logic upper electrode film 250a and the insulating film 230a for a logic dielectric film are simultaneously patterned, photolithography is performed only one time, which makes the process more efficient. If the logic upper electrode film 250a and the insulating film 230a for a logic dielectric film are simultaneously patterned, the logic upper electrode film 250a and the insulating film 230a for a logic dielectric film can be aligned. When the logic upper electrode film 250a and the insulating film 230a for a logic dielectric film are patterned, the bit line 290 of the memory region A is etched; therefore, the logic upper electrode 250 and the logic dielectric film 230 that are used in the logic capacitor 200 do not exist on the bit line 290.

As shown in FIG. 5F, the logic lower metal electrode 210 and bit line 290 are etched, so that the completed logic lower metal electrode 210 occupies a larger area than the logic dielectric film 230 existing at the upper side of the logic lower metal electrode 210 and the logic upper metal electrode 250 existing at the upper side of the logic dielectric film 230. As a result, in the following process, a logic upper metal electrode contact 222d and the logic lower metal electrode contact 222c can be simultaneously formed.

Subsequently, as shown in FIG. 5G, the second interlayer insulating film 240 and the second metal contact 222 are formed on the result of FIG. 5F (S80).

The second interlayer insulating film 240 can be formed by the same process of forming the first interlayer insulating film 140.

The second metal contacts 222 can be formed through the second interlayer insulating film 240. The second metal contacts 222 include a contact 222a to be electrically connected to the cell capacitor 400 in the memory region A, and contacts 222c and 222d to be electrically connected to the logic capacitor 200 in the logic region B. To be more specific, the second metal contacts 222 include the lower metal electrode contact 222c to be electrically connected to the lower metal electrode 210 of the logic capacitor 200 and the upper metal electrode contact 222d to be electrically connected to the upper metal electrode 250. Since the lower metal electrode 210 occupies a larger area than the upper metal electrode 250, the lower metal electrode contact 222c and the upper metal electrode contact 222d can be simultaneously formed, which simplifies the fabrication process.

Subsequently, referring to FIG. 5H, the cell capacitor 400 is formed on the result of FIG. 5G in the memory region A (S90).

The cell capacitor 400 may be formed in a cylindrical shape, as shown in FIGS. 1 and 10. The cell capacitor 400 is an MIM capacitor having a metal-dielectric film-metal structure which includes the cell lower metal electrode 410, the cell dielectric film 430, and the cell upper metal electrode 450.

The metal-dielectric film-metal structure constituting the cell capacitor 400 may be substantially equal to that of the logic capacitor 200.

Particularly, like the dielectric film 230 of the logic capacitor 200, the cell dielectric film 430 of the cell capacitor 400 may be a single film or multilayered film made of oxides or nitrides of Al, Hf, Zr, La, Si, Ta, Ti, Sr, Ba, Pb, Cr, Mo, W, Y, Mn, or mixtures thereof. Since the dielectric film 230 of the logic capacitor 200 uses the same material as the cell dielectric film 430 of the cell capacitor, the dielectric films can be formed using the same fabrication equipment. Particularly, if the dielectric film is formed of high dielectric materials, the cell capacitor 400 and the logic capacitor 200 will have better electrical characteristics. Materials of the insulating film 230a for a logic dielectric film may be equal to those of the cell dielectric film 230 that is used in manufacturing the cell capacitor 400 to be described below. If materials of the cell capacitor 400 are equal to those of the dielectric film of the logic capacitor 200, they can be formed in the same equipment.

Next, as shown in FIG. 5H, subsequent processes, in which the third interlayer insulating film 340 is formed on the result of FIG. 5G and the metal wire 500 is then formed on the result of FIG. 5H, are performed so as to complete the formation of the semiconductor device (S100). The detailed description of subsequent processes will be omitted since they are well known. According to steps of a process extensively known to those skilled in the semiconductor device field, a step of forming the metal wires 500 to conduct an input and an output of electrical signals in a logic element of each transistor and capacitor, a step of forming a passivation layer, and a step of packaging the substrate are additionally carried out to complete a semiconductor device.

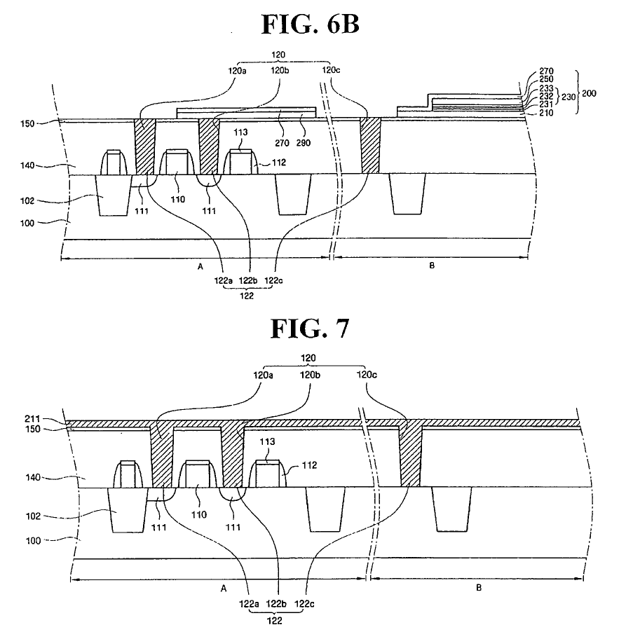

Hereinafter, a method of fabricating the semiconductor device according to the second embodiment of the present invention will be described with reference to FIGS. 4, and 6A to 6B. FIG. 4 is a flow chart illustrating the method of fabricating the semiconductor device according to the second embodiment of the present invention. FIGS. 6A and 6B are cross-sectional views of structure in the middle of the process, illustrating the method of fabricating a semiconductor device according to the second embodiment of the present invention.

The same components shown in FIGS. 6A and 6B as those of FIGS. 5A and 5H are denoted by the same reference numerals, and the description thereof will be omitted.

The method of fabricating the semiconductor device according to the second embodiment of the present invention, to be described with reference to FIGS. 6A and 6B, is substantially equal to the method of fabrication that has been described with reference to FIGS. 5A to 5H. However, the method of fabricating the semiconductor device according to the second embodiment is different from the method of fabricating the semiconductor device according to the first embodiment of the present invention in that a hard mask layer 270a is formed after patterning the logic upper metal electrode film 250a and the insulating film 230a for a logic dielectric film.

The hard mask layer 270a is formed on the resulting structure shown in FIG. 5E (S60). The hard mask film 270a is used in the patterning process of the bit line, can be a film of silicon nitride film, silicon oxide film, polysilicon film, or a mixture thereof, but not limited thereto. The hard mask layer 270a can be formed by PVD, CVD, LPCVD (Low Pressure Chemical Vapor Deposition), etc. However, since the hard mask layer 270a can be formed according to processes extensively known to those skilled in the art of the present invention, detailed description of the known processes will be omitted.

Since the dielectric film 230 that is used in the logic capacitor does not exist on the bit line 290, when the hard mask layer 270a is formed, the hard mask layer 270a may be formed at the upper side of the bit line 290 of the memory region A and at the upper or lateral side of the logic upper metal electrode 250, the logic dielectric film 230 and the logic lower metal electrode 210 of the logic region B. That is, the hard mask 270 exists on the bit line 290 without the logic dielectric film 230 interposed therebetween.

After the hard mask layer 270a is formed, the hard mask layer 270a, the bit line, and the lower metal electrode metal film 210a are patterned (S70).

Since the hard mask layer 270a is present in this embodiment, etching is more accurate as compared to when using only photoresist for patterning, and fine patterns can be formed. The bit line 290 and the lower metal electrode 210 are simultaneously formed of the same metal film, and the dielectric film 230 is not formed on the bit line 290; therefore, the hard mask layer 270a can be formed on the bit line 290. As a result, the bit line 290 can be fine-patterned, which leads to more advanced integration of the semiconductor device and simplification of the process.

Hereinafter, a process of fabricating the semiconductor device according to the third embodiment of the present invention will be described with reference to FIGS. 5A to 5H and FIG. 7. FIG. 7 is a cross-sectional view of a structure in the middle of the process, illustrating the fabricating process of the semiconductor device according to the third embodiment of the present invention. The same components shown in FIG. 7 as those of FIGS. 5A and 5H are denoted by the same reference numerals, and the description thereof will be omitted.

The method of fabricating the semiconductor device according to the third embodiment of the present invention, to be described with reference to FIG. 7, is substantially equal to the method of fabrication that has been described with reference to FIGS. 5A to 5H. However, the method of fabricating the semiconductor device according to the third embodiment is different from the method of fabricating the semiconductor device according to the first embodiment of the present invention in that the first metal contact 122, the bit line, and the lower metal electrode metal film 210a are formed in one step thus to improve efficiency in the fabrication process.

That is, as shown in FIG. 7, a transistor is formed in the semiconductor substrate 100, and the first interlayer insulating film 140 is then formed to cover the transistor. Then, the first metal contact, the bit line and a metal film 211 for a lower metal electrode are formed. Processes that are followed after forming the insulating film 230a for a logic dielectric film on the first metal contact, the bit line and the lower metal electrode metal film 211 are the same as the method of fabricating the semiconductor device according to the first embodiment of the present invention.

In the semiconductor device that is fabricated by the method illustrated in FIG. 7, the first metal contact 122, the bit line 290 and the lower metal electrode 210 are formed of the same metallic material.

While the foregoing has described what are considered to be the best mode and/or other preferred embodiments, it is understood that various modifications can be made therein and that the invention or inventions may be implemented in various forms and embodiments, and that they may be applied in numerous applications, only some of which have been described herein. It is intended by the following claims to claim that which is literally described and all equivalents thereto, including all modifications and variations that fall within the scope of each claim.

As described above, embodiments of the present invention provide a semiconductor device that is fabricated in a more efficient process. Metal pollution is decreased by simultaneously forming the bit line of the memory region and the logic lower metal electrode of the logic region, as compared to a process whereby a logic lower metal electrode is formed at the time of metal wiring. Moreover, high dielectric material that has been otherwise avoided due to metal pollution problems can be used to form a dielectric film of the logic capacitor, and a hard mask layer can be formed on the bit line of the memory region to improve accuracy and integration. As a result, the semiconductor device has better electrical characteristics, and the bit line of the memory region can be finely patterned.

What is claimed is:

1. A semiconductor device comprising:
a substrate including transistors and partitioned into a memory region and a logic region;
a bit line electrically connected to at least one of the transistors in the memory region; and
a logic capacitor formed on the logic region,
wherein the logic capacitor includes a logic lower metal electrode of a same layer as that of the bit line, a logic dielectric film, and a logic upper metal electrode.

2. The semiconductor device of claim 1, wherein the logic dielectric film is present exclusively in the logic region and is not present on the bit line of the memory region.

3. The semiconductor device of claim 1, wherein a material of the logic lower metal electrode is the same as the bit line.

4. The semiconductor device of claim 1, further comprising:
a hard mask layer aligned with the bit line and the logic upper metal electrode on the bit line and the logic upper metal electrode.

5. The semiconductor device of claim 1, wherein the dielectric film is a single film or multilayered film made of oxides and nitrides of Al, Hf, Zr, La, Si, Ta, Ti, Sr, Ba, Pb, Cr, Mo, W, Y, Mn, or mixtures thereof

6. The semiconductor device of claim 1, wherein the logic upper metal electrode is aligned with the logic dielectric film.

7. The semiconductor device of claim 1, wherein the logic dielectric film is formed to have an area smaller than the area of the logic lower metal electrode.

8. The semiconductor device of claim 1, further comprising:
a cell capacitor electrically connected to the transistor,
wherein the cell capacitor includes a cell lower metal electrode, a cell dielectric film, and a cell upper metal electrode, and
the logic dielectric film and the cell dielectric film of the cell capacitor are made of the same material.

9. The semiconductor device of claim 1, wherein a bit line contact connecting the transistor and the bit line, the bit line, and the logic lower metal electrode are made of the same metallic material.

10. The semiconductor device of claim 1, wherein the bit line and the logic lower metal electrode are made of W or TiN.

11. A method of fabricating a semiconductor device, the method comprising:
providing a substrate including transistors formed thereon and divided into a memory region and a logic region; and
forming a bit line electrically connected to at least one of the transistors in the memory region and forming a logic capacitor on the logic region,
wherein the forming of the logic capacitor includes forming a logic lower metal electrode, a logic dielectric film, and a logic upper metal electrode.

12. The method of claim 11, wherein the logic dielectric film is present exclusively in the logic region, and not in the memory region.

13. The method of claim 11, wherein forming the bit line and forming the logic lower metal electrode of the capacitor are performed at the same time so that the material of the logic lower metal electrode is the same as that of the bit line.

14. The method of claim 11, wherein the logic dielectric film is a single film or multilayered film made of oxides or nitrides of Al, Hf, Zr, La, Si, Ta, Ti, Sr, Ba, Pb, Cr, Mo, W, Y, or Mn, or mixtures thereof

15. The method of claim 11, wherein a bit line contact connecting the transistor and the bit line, the bit line, and the logic lower metal electrode are made of the same metallic material.

16. The method of claim 11, wherein the bit line and the logic lower metal electrode are made of W or TiN.

17. A method of fabricating a semiconductor device comprising:
providing a substrate including transistors formed thereon and divided into a memory region and a logic region;
forming an interlayer insulating film on the substrate;
forming a metal film for a bit line and a logic lower metal electrode on the interlayer insulating film;
forming an insulating film for a logic dielectric film on the metal film for the bit line and the logic lower metal electrode;
forming a metal film for a logic upper metal electrode on the insulating film for a logic dielectric film;
patterning the metal film for the logic upper metal electrode and the insulating film for the logic dielectric film to form the logic upper metal electrode and the logic dielectric film; and
forming a bit line electrically connected to the transistor through a contact formed through the interlayer insulating film and forming a logic lower metal electrode under the patterned logic dielectric film by patterning the metal film for the bit line and the logic lower metal electrode, so that a bit line is formed in the memory region and so that a logic capacitor is formed in the logic region.

18. The method of claim 17, further comprising:
forming a hard mask layer on the logic upper metal electrode and the metal film for the bit line and the logic lower metal electrode after the patterning of the logic upper metal and the logic dielectric film to form the logic upper metal electrode and the logic dielectric film,
wherein the patterning of the metal film for the bit line and the logic lower metal electrode after the forming of the hard mask layer includes aligning the hard mask layer with the bit line and the logic lower metal electrode or the logic upper metal electrode by patterning the hard mask layer.

19. The method of claim 17, wherein the logic dielectric film is a single film or multilayered film made of oxides or nitrides of Al, Hf, Zr, La, Si, Ta, Ti, Sr, Ba, Pb, Cr, Mo, W, Y, Mn, or mixtures thereof.

20. The method of claim 17, wherein the logic upper metal electrode and the logic dielectric film are simultaneously patterned such that the logic upper metal electrode is aligned with the logic dielectric film.

21. The method of claim 17, further comprising:
forming a second interlayer insulating film on the bit line and the logic capacitor after the bit line and the logic capacitor are formed; and
simultaneously forming a logic upper metal electrode contact and a logic lower metal electrode contact that are electrically connected to the logic upper metal electrode and the logic lower metal electrode of the logic capacitor, respectively, in the second interlayer insulating film,
wherein the forming of the logic lower metal electrode includes patterning the logic lower metal electrode in an area larger than the area of the logic dielectric film.

22. The method of claim 17, further comprising:
forming a cell capacitor that is electrically connected to the transistor on the second interlayer insulating film, wherein the cell capacitor comprises a cell lower metal electrode, a cell dielectric film, and a cell upper metal electrode; and wherein the cell dielectric film and the logic dielectric film are made of the same material.

23. The method of claim 22, wherein each of the cell dielectric film and the logic dielectric film is a single film or a multilayered film made of oxides or nitrides of Al, Hf, Zr, La, Si, Ta, Ti, Sr, Ba, Pb, Cr, Mo, W, Y, Mn, or mixtures thereof
